(19) United States
(12) Patent Application Publication
(10) Pub. No.: US 2007/0063333 A1
(43) Pub. Date: Mar. 22, 2007

(54) Semiconductor package with internal shunt resistor

(75) Inventor: Mohamad Ashraf Bin Mohd Arshad, K. Lumpur (MY)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/231,595

(22) Filed: Sep. 20, 2005

(51) Int. Cl. H01L 23/48

(52) U.S. Cl. 257/690

(57) ABSTRACT

According to an embodiment of the invention, a semiconductor package has been provided that includes a die, a first lead pad, a second lead pad, a circuit component, a first wire bond, and a second wire bond. The die is supported on a die pad. The circuit component has a first end and a second end. The first end is communicatively coupled to the first lead pad and the second end is communicatively coupled to the second lead pad. The first wire bond is communicatively coupled to the die and the first lead pad and provides a communication path between the die and the first end of the circuit component through the first lead pad. The second wire bond is communicatively coupled to the die and the second lead pad and provides a communication path between the die and the second end of the circuit component through the second lead pad.

### TECHNICAL FIELD OF THE INVENTION

This invention relates generally to the field of semiconductor devices and, more particularly, to a semiconductor package with an internal shunt resistor.

### BACKGROUND OF THE INVENTION

Semiconductor packages may generally include a die embedded with a mold compound. Such semiconductor packages may communicate with external components, for example, on a circuit board, using a variety of components such as leads or pads. One type of semiconductor package is a quad-flat no-lead (QFN) semiconductor package. QFN semiconductor packages are a type of leadless leadframe semiconductor package.

When modifications are made to a semiconductor package such as a QFN semiconductor package or other semiconductor package, a variety of difficulties can be encountered. For example, modifications may change the location of the die with the semiconductor package or the location of leads or pads in the package.

### SUMMARY OF THE INVENTION

According to an embodiment of the invention, a semiconductor package has been provided that includes a die, a first lead pad, a second lead pad, a circuit component, a first wire bond, and a second wire bond. The die is supported on a die pad. The circuit component has a first end and a second end. The first end is communicatively coupled to the first lead pad and the second end is communicatively coupled to the second lead pad. The first wire bond is communicatively coupled to the die and the first lead pad and provides a communication path between the die and the first end of the circuit component through the first lead pad. The second wire bond is communicatively coupled to the die and the second lead pad and provides a communication path between the die and the second end of the circuit component through the second lead pad.

Certain embodiments of the invention may provide numerous technical advantages. For example, a technical advantage of one embodiment may include the capability to integrate a resistor into a semiconductor package between lead pads. Other technical advantage of other embodiment may include the capability to integrate a resistor into a semiconductor package without modifying a footprint for the semiconductor package and the capability to integrate a resistor into a semiconductor package without modifying a standard bond insert used in construction of the semiconductor package.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments of the present invention and its advantages, reference is now made to the following description, taken in conjunction with the accompanying drawings, in which:

FIG. 1A shows a top cut-away view of a semiconductor assembly, according to an embodiment of the invention;

FIG. 1B shows a top cut-away view of a semiconductor package, according to an embodiment of the invention;

FIG. 1C shows a top exploded view of a portion 1C of FIG. 1B;

FIG. 2A shows a top cut-away view of a semiconductor assembly;

FIGS. 2C and 2D show top exploded views of portions 2C and 2D from FIG. 2B; and

FIGS. 3A, 3B, and 4 shows standard components that may be used in conjunction with the semiconductor assemblies of FIGS. 1A and 2A.

### DETAILED DESCRIPTION OF EXAMPLE EMBODIMENTS OF THE INVENTION

It should be understood at the outset that although example embodiments of the present invention are illustrated below, the present invention may be implemented using any number of techniques, whether currently known or in existence. The present invention should in no way be limited to the example embodiments, drawings, and techniques illustrated below, including the embodiments and implementation illustrated and described herein. Additionally, the drawings are not necessarily drawn to scale.

For a variety of reasons, it may become desirable to provide features in a semiconductor package that can enhance the performance of a die within such a semiconductor package. For example, it may be desirable to incorporate a resistor that is to too large to be embedded within the die. Difficulties with the incorporation of such features in the semiconductor package, however, may arise. For example, an incorporation of an extra feature may require the die to be shifted to one side of the semiconductor package, disturbing standard package footprints expected by circuit boards on which the semiconductor package will be mounted. Additionally, modifications to the semiconductor package may perturb a standard bond insert utilized in manufacturing the semiconductor package. Accordingly, some embodiments of the invention recognize configurations and techniques which allow an integration of features for a die within a semiconductor package while minimizing undesirable effects typically associated with the integration of such features.

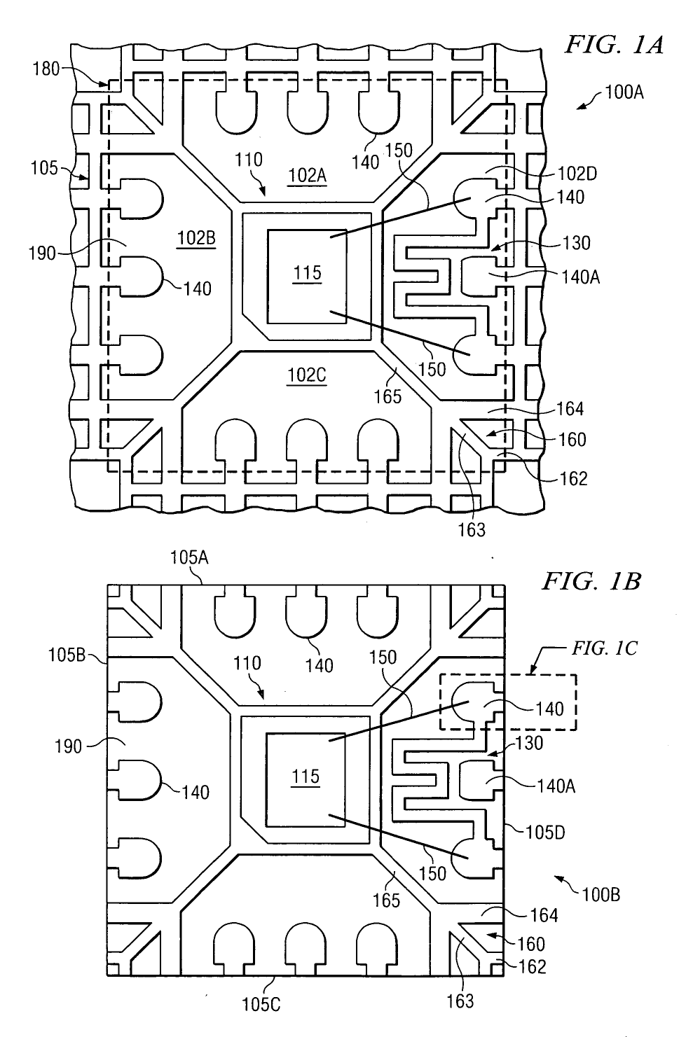

FIG. 1A shows a top cut-away view of a semiconductor assembly 100A, according to an embodiment of the invention. For purposes of brevity, only one semiconductor assembly 100A is shown. FIG. 1B shows a top cut-away view of a semiconductor package 100B, according to an embodiment of the invention. The semiconductor package 100B of FIG. 1B includes the components of the semiconductor assembly 100A of FIG. 1A with the outer frame 105 removed during a singulation process along line 180. As described in further details below, the semiconductor assembly 100A may be one of a plurality of semiconductor assemblies 100A that are side-by-side in production. During production and after incorporation of the appropriate components in the semiconductor assembly 100A, the semiconductor assembly 100A may be singulated to produce a semiconductor package 100B, for example, as shown in FIG. 1B.

The semiconductor assembly 100A of FIG. 1A includes an outer frame 105, a die pad 110, a plurality of lead pads 140, a plurality of die pad support straps 160, and a shunt resistor 130. In other embodiments, the semiconductor assembly 100A may include more, less, or different components.

The outer frame 105 in the embodiment of FIG. 1A has a generally square design. Adjacent the edges of the outer frame 105 is a first side 102A, a second side 102B, a third side 102C, and a fourth side 102D of the semiconductor assembly 100A. In this embodiment, the first side 102A and third side 102C are generally orthogonal to the second side 102B and fourth side 102D. However, in other embodiments, the first side 102A and third side 102C may not be orthogonal to the second side 102B and fourth side 102D. And, in yet other embodiments, the semiconductor assembly 100A may have three sides or five or more sides.

In this embodiment, three lead pads 140 are shown coupled to the outer frame 105, adjacent each of the first side 102A, the second side 102B, the third side 102C, and the fourth side 102D. In other embodiments, more or less than three lead pads 140 may be coupled to the portions of the outer frame 105 adjacent each of the respective first side 102A, second side 102B, third side 102C, and fourth side 102D of the semiconductor assembly 100A.

The outer frame 105 in particular embodiments may provide support for the lead pads 140 and/or other components in the semiconductor assembly 100A during production of the semiconductor assembly 100A. After a mold compound 190 has been placed around components 100A, the outer frame 105 may be removed during a singulation process, which removes portions outside line 180. As briefly referenced above, the singulation process may produce a semiconductor package 100B, for example, as shown in FIG. 1B.

The die pad 110 is shown supporting a die 115. In production, the die 115 may be mounted to the die pad 110 using a variety of die bonds, including epoxy, polyimide, other adhesive chemistries, mixture of such chemistries, solder, a gold-silicon Eutectic layer, or other suitable material for bonding the die 115 to the substrate die pad. The die 115 may provide the foundation for a variety of semiconductor features, including but not limited to, analog and/or digital circuits such as digital to analog converters, computer processor units, amplifiers, digital signal processors, controllers, transistors, or other semiconductor features or other integrated circuits. The die 115 may comprise a variety of materials including silicon, gallium arsenide, or other suitable substrate materials. Although a die 115 has been shown mounted on the die pad 110 in this embodiment, a variety of other passive and active components may be utilized in lieu of or in addition to the die 115 in other embodiments.

In particular embodiments, the die support straps 160 may provide structural support for the die pad 110 and die 115 during and/or after production of the semiconductor assembly 100A. The die support straps 160 in this embodiment include a first portion 162, a second portion 163, a third portion 164, and a fourth portion 165.

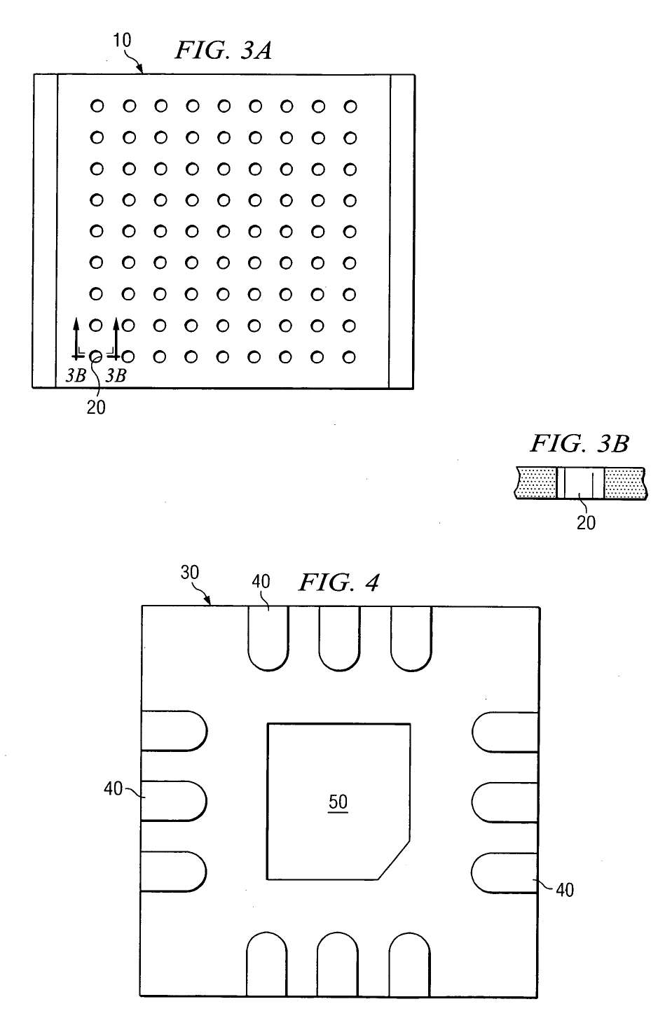

Wire bonds 150 may be coupled between the die 115 and the lead pads 140 to facilitate communication of the die 115 with components external to the die 115. For example, the lead pads 140 in particular embodiments may be in communication with corresponding pads on a printed circuit board. An example of a package footprint 30 for a printed circuit board is described below with reference to FIG. 4. In other embodiments, the lead pads 140 may be coupled to a lead extending to the circuit board. The wire bonds 150 may be coupled to the lead pads 140 using any of variety of coupling techniques, including but not limited to standard wire-bonding or stud-stitch bonding (SSB). With such wire bond 150, electrical current may be communicated to and from the die 115 to and from the lead pads 140.

The shunt resistor 130 in this embodiment is positioned between two leads pads 140 adjacent the fourth side 102D. In operation, the shunt resistor 130 may provide resistance to implement a particular circuit feature for the semiconductor package 100B of FIG. 1B (singulated from the semiconductor assembly 100A of FIG. 1A). For example, the shunt resistors 130 may provide a parallel resistive path for an electrical current flowing from the die 115. This parallel path may be a parallel path to a printed circuit board or a parallel path to path within the die 115.

Examples communication paths in the semiconductor package 100B of FIG. 1B (singulated from the semiconductor assembly 10A of FIG. 1A) include, but are not limited to the following. Electrical current may travel from the die 115 to a first lead pad 140 through the wire bond 150. From the first lead pad 140, at least a portion of the electrical current may travel through the shunt resistor 130 to a second lead pad 140. From the second lead pad 140, at least another portion of the electrical may travel either to a printed circuit board in one embodiment or back to the die 115 in another embodiment, for example, through another wire bond 150. Other suitable communication paths may additionally be established

The shunt resistor 130 may be made of a variety of materials, including a variety of metals such as copper. To suit particular configurations and/or particular features in the die 115 and/or a component to which die communicates, the amount of resistance in the shunt resistor 130 may varied by changing a length and/or a cross-sectional area of the shunt resistor 130. To facilitate the placement of the shunt resistor 130 between the lead pads 140 in this embodiment, one of the lead pads 140A has been slightly modified. In other embodiments, lead pad 140A may be removed.

Although a shunt resistor 130 is shown in the embodiment of FIGS. 1A and 1B, in other embodiments, other circuit components may be utilized between lead pads 140. Examples of other circuit components include passive components such as capacitors, inductors, and other resistors and active components. Accordingly, the shunt resistor 130, described herein, is but one example of a circuit component that may be utilized according to teachings of some embodiments of the invention.

After the lead pads 140, the die 115, the wire bonds 150, the shunt resistor 130, and any other suitable components have been incorporated into the semiconductor assembly 100A of FIG. 1A, a mold compound 190 may be disposed around the lead pads 140, the die 115, the wire bonds 150, the shunt resistor 130, and any other suitable components that have been incorporated into the semiconductor assembly 100A. One suitable molding process is an injection molding process. However, other suitable molding process may be utilized to place mold compound 190 around the lead pads 140, the die 115, the wire bonds 150, the shunt resistor 130, and any other suitable components have been incorporated into the semiconductor assembly 100A.

As briefly referenced above, in operation, several semiconductor assemblies 100A such as that shown in FIG. 1A may be positioned side-by-side. Accordingly, after placement of the components in the semiconductor assembly 100A and appropriate curing of the mold compound 190, the semiconductor assembly 100A may be singulated along line 180 to remove the outer frame 105 and produce the semiconductor package 100B of FIG. 1B. A variety of singulation processes should become apparent to one of ordinary skill in the art, including, but not limited to sawing processes.

Although the semiconductor package 100B of FIG. 1B takes on a generally square configuration, in other embodiments the semiconductor package 100B may take on a variety of other configurations, including, but not limited to triangular, rectangular, circular, pentagonal, and hexagonal configurations. The semiconductor package 100B of FIG. 1B is shown as Quad Flat No Lead (QFN) semiconductor package. However, the techniques and components described herein may be utilized with other semiconductor package designs, including, but not limited to, non-QFN semiconductor packages.

The utilization of the shunt resistor 130 between lead pads 140 may allow integration of a circuit feature, such as shunt resistor 130 that traditionally may be too large for the die 115, into a semiconductor package 100B while maintaining standard interfaces of the lead pads 140 of the semiconductor package 100B with a package footprint 30 shown in FIG. 4. Additionally, the integration of the shunt resistor 130 between lead pads 140 in particular embodiments may allow the die 115 to remain in the center of the semiconductor package 100B.

FIG. 1C shows a top exploded view of a portion 1C of FIG. 1B. The shunt resistor 130 may be coupled at an angle 145 that minimizes perturbation to the intended operation of the shunt resistor 130. For example, a current may travel through the wire bond 150 in a direction indicated by arrow 170. From the end of the wire bond 150, the design of the shunt resistor 130 may intend for the current to travel directly to the shunt resistor 130, for example, as opposed to traveling through other portions of the lead pad 140. Accordingly, the creation of angle 145 in FIG. 1C (e.g., by selecting the appropriate bonding location of the wire bond 150 on the lead pad 140) may minimize the likelihood of the current traveling through other portions of the lead pad 140.

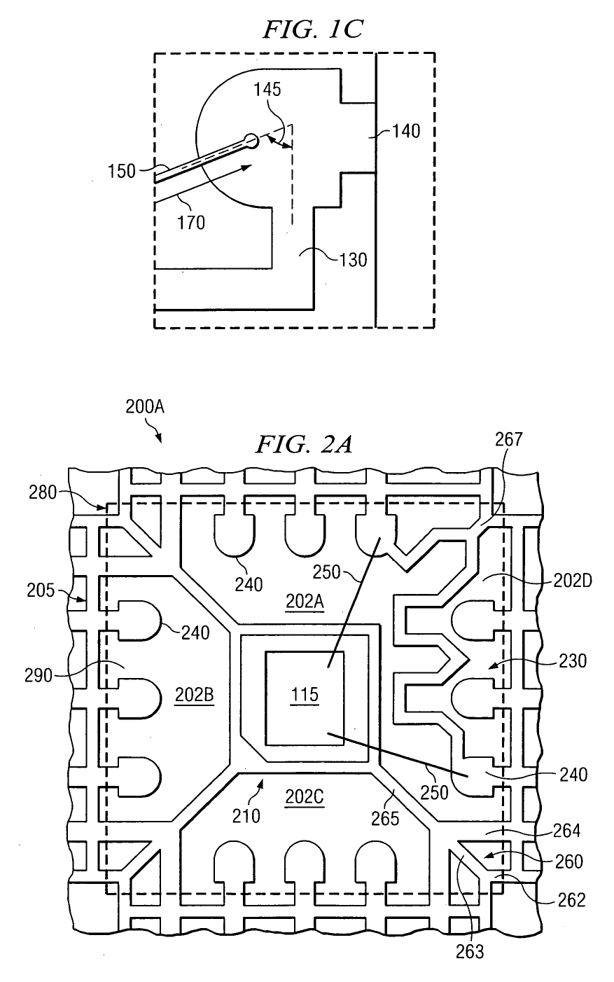

FIG. 2A shows a top cut-away view of a semiconductor assembly 200A, according to another embodiment of the invention. FIG. 2B shows a top cut-away view of a semiconductor package 200B, according to an embodiment of the invention. Similar to the semiconductor assembly 100A of FIG. 1A, the semiconductor assembly 200A of FIG. 2A may have a first side 202A, a second side 202B, a third side 202C, and a fourth side 202D and may include an outer frame 205, a die pad 210 with a die 215, a plurality of lead pads 240, a plurality of die pad support straps 260 (with a first portion 262, a second portion 263, a third portion 264, and a fourth portion 265), mold compound 290, and a shunt resistor 230. The semiconductor assembly 200A of FIG. 2A additionally includes a support strap 267 for the shunt resistor 230. In a manner similar to that described above with reference to the semiconductor package 100B of FIG. 1B, the semiconductor package 200B of FIG. 2B includes the components of the semiconductor assembly 200A of FIG. 2A with the outer frame 205 removed during a singulation process along line 280. Any of a variety of singulation process may be utilized, including, but not limited to sawing.

In the embodiment of FIGS. 2A and 2B, the shunt resistor 230 is positioned between a lead pad 240 on the fourth side 202D and a lead pad 240 on the first side 202A. The shunt resistor 230 of FIG. 2A is longer than the shunt resistor 130 of FIGS. 1A and 1B. Accordingly, the embodiments of FIG. 2A and 2B replaces a portion of one of the die support straps 260 with a support strap 267 designed to support the shunt resistor 230.

In a manner similar to that described above with reference to FIGS. 1A and 1B, although a shunt resistor 230 is shown in the embodiment of FIGS. 2A and 2B, in other embodiments, other circuit components may be utilized between lead pads 240. Examples of other circuit components include passive components such as capacitors, inductors, and other resistors and active components. Accordingly, the shunt resistor 230, described herein, is but one example of a circuit component that may be utilized according to teachings of some embodiments of the invention.

FIGS. 2C and 2D show top exploded views of portions 2C and 2D from FIG. 2B. FIG. 2C shows in more detail the support of the shunt resistor 230 by the support strap 267. A lower portion 268 of the support strap 267 may be configured similar to the first portion 262 of the die pad support strap 260.

In a manner similar to that described with reference to FIG. 1C, FIG. 2D shows how the shunt resistor 230 may be coupled to the lead pad 140 at an angle 245 that minimizes perturbations in the operation of the shunt resistor 230. For example, a current may travel through the wire bond 250 in a direction indicated by arrow 270. From the end of the wire bond 250, the design of the shunt resistor 230 may intend for the current to travel directly to the shunt resistor 230, for example, as opposed to traveling through other portions of the lead pad 240. Accordingly, the creation of angle 245 in FIG. 2D (e.g., by selecting the appropriate bonding location of the wire bond 250 on the lead pad 240) may minimize the likelihood of the current traveling through other portions of the lead pad 240.

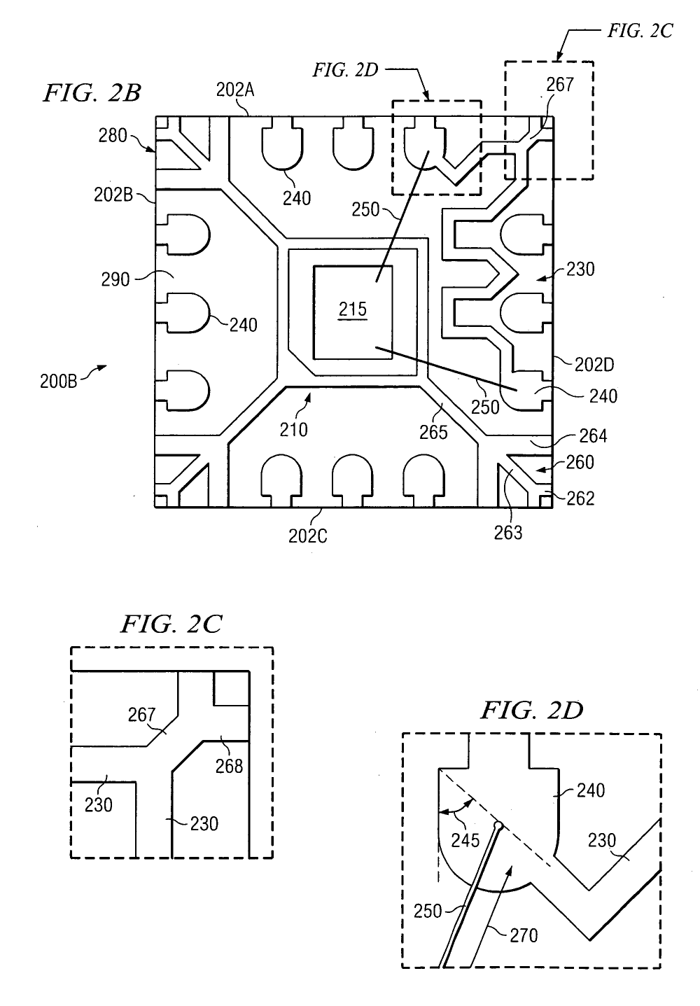

FIGS. 3A and 3B show standard components that may be used in conjunction with the semiconductor assemblies 100A and 200A of FIGS. 1A and 2A. FIG. 3A shows a standard bond insert 10 with vacuum holes 20. FIG. 3B shows a cross sectional view taken across lines 3B-3B of FIG. 3A. The standard bond insert 10 may be utilized to produce the semiconductor assemblies 100A and 200A of FIGS. 1A and 2A.

FIG. 4 shows a standard package footprint 30 with pads 40 to support lead pads 140, 240, and a pad 50 to support the die pads 110, 210—from FIGS. 1A, 1B, 2A, and 2B. Such standard package footprints 30 expect a complimentary semiconductor package. According to particular embodiments, the semiconductor packages 100B, 200B may provide such complimentary semiconductor packages. For example, as briefly referenced above, the die 115, 215 in particular embodiments may not need to be moved from the center of the semiconductor package.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

What is claimed is:

1. A semiconductor package, comprising:
a mold compound body;
a die pad operable to support a die, the die pad and the die at least partially encapsulated by the mold compound body;
a first lead pad and a second lead pad, each at least partially encapsulated by the mold compound body;
a shunt resistor having a first end and a second end, the first end communicatively coupled to the first lead pad and the second end communicatively coupled to the second lead pad;
a first wire bond communicatively coupled to the die and the first lead pad, the first wire bond providing a communication path between the die and the first end of the shunt resistor through the first lead pad; and
a second wire bond communicatively coupled to the die and the second lead pad, the second wire bond providing a communication path between the die and the second end of the shunt resistor through the second lead pad.

2. The semiconductor package of claim 1, wherein
the semiconductor package has at least three sides, and
the first lead pad and the second lead pad are on the same side of the semiconductor package.

3. The semiconductor package of claim 1, wherein
the semiconductor package has at least three sides, and
the first lead pad and the second lead pad are on different ones of the at least three sides.

4. The semiconductor package of claim 3, wherein the different ones of the at least three sides are orthogonal to one another.

5. A method of providing a circuit feature in a semiconductor package, the method comprising:
communicating, through a first wire bond, electrical current from a die to a first lead pad in the semiconductor package;
communicating, through a circuit component, at least a portion of the electrical current from the first lead pad to a second lead pad in the semiconductor package, the circuit component providing the circuit feature and the circuit component separate from the die.

6. The method of claim 5, further comprising:
communicating, through a second wire bond, at least another portion of the at least a portion of the electrical current from the second lead pad to the die.

7. The method of claim 5, further comprising:
communicating at least another portion of the at least a portion of the electrical current from the second lead pad to a printed circuit board external of the semiconductor package.

8. The method of claim 5, further comprising:
communicating, through a second wire bond, another electrical current from the die to the second lead pad, wherein a path from the die to the second lead pad through the second wire bond is parallel to a path from the die to the second lead pad through the first wire bond and the circuit component.

9. The method of claim 5, wherein the circuit component comprises a shunt resistor.

10. The method of claim 5, wherein the circuit component comprises a passive component.

11. The method of claim 10, wherein the passive component is selected from the group consisting of capacitors, inductors, and resistors.

12. A semiconductor package, comprising:
a die pad operable to support a die;
a first lead pad and a second lead pad;
a circuit component having a first end and a second end, the first end communicatively coupled to the first lead pad and the second end communicatively coupled to the second lead pad; and
a first wire bond communicatively coupled to the die and the first lead pad, the first wire bond providing a communication path between the die and the first end of the circuit component through the first lead pad.

13. The semiconductor package of claim 12, further comprising:
a second wire bond communicatively coupled to the die and the second lead pad, the second wire bond providing a communication path between the die and the second end of the circuit component through the second lead pad.

14. The semiconductor package of claim 12, wherein
the semiconductor package has at least three sides, and
the first lead pad and the second lead pad are on the same side of the semiconductor package.

15. The semiconductor package of claim 12, wherein
the semiconductor package has at least three sides, and
the first lead pad and the second lead pad are on different ones of the at least three sides.

16. The semiconductor package of claim 15, wherein the different ones of the at least three sides are orthogonal to one another.

17. The semiconductor package of claim 12, wherein the circuit component comprises a passive component.

18. The semiconductor package of claim 17, wherein the passive component is selected from the group consisting of capacitors, inductors, and resistors.

19. The semiconductor package of claim 12, further comprising:
a support strap positioned between the first lead pad and the second lead pad, the support strap operable to support the circuit component.

20. The semiconductor package of claim 12, wherein the semiconductor package is a quad flat no-lead semiconductor package.
